(19) United States
(12) Patent Application Publication
(10) Pub. No.: US 2008/0144144 A1
(43) Pub. Date: Jun. 19, 2008

(54) Confirming a state of a device

(75) Inventor: Brian Smithson, Sunnyvale, CA (US)

Correspondence Address: HICKMAN PALERMO TRUONG & BECKER, LLP, 2055 GATEWAY PLACE, SUITE 550, SAN JOSE, CA, 95110, US

(73) Assignee: Ricoh Corporation Ltd.

(21) Appl. No.: 11/591,079

(22) Filed: Oct. 31, 2006

(51) Int. Cl. G03F 3/08

(52) U.S. Cl. 358/520

(57) ABSTRACT

A method and apparatus for confirming, to a walk-up user of a device, that the device may be trusted is provided. The walk-up user may confirm that the device is still operating in the same state (“the prior state”) in which the device was previously operating. The prior state of the device may be any earlier state of the device in which the device is guaranteed to be trustworthy. For example, the prior state may correspond to the state that the device is in when it is deployed or configured by an administrator. The prior state may be a security state or an operational state of the device. The walk-up user may confirm the state of the device through a physical interface provided by the device or by using a portable device operationally connected to the device.

### FIELD OF THE INVENTION

The present invention generally relates to confirming a state of a device.

### BACKGROUND

It is desirable for a person to know whether he or she may trust a particular device. For example, before using a multi-function peripheral, it would be advantageous for a user to know whether the security of the multi-function peripheral has been compromised.

Typically, in order to establish a trust relationship with a device, a person uses a computer that the user already trusts. To illustrate, a user that wishes to determine whether he or she may trust a server may use his or her own desktop computer that has already been established as being trustworthy. The desktop computer may communicate with the server, use a cryptographic process to determine whether the server may be trusted, and thereafter report the results to the user of the desktop computer. Unfortunately, such a process to establish a trust relationship cannot be employed when the user does not have access to another device to help perform the computations involved in the cryptographic process.

This problem may be experienced by a user (a “walk-up user”) who walks up to a device for purposes of using the device, such as when a user walks up to a multi-function peripheral to use the multi-function peripheral. Since the walk-up user does not carry a desktop computer that is operationally connected to the device, the user cannot verify, using this approach, whether the multi-function peripheral may be trusted.

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

### SUMMARY

Techniques are provided for confirming, to a user, that a device may be trusted. The techniques described herein may be used by a user (a “walk-up user”) who walks up to the device for purposes of using the device. Embodiments of the invention may be used to confirm, to the walk-up user, that the device is still operating in the same state (“the prior state”) in which the device was previously operating. The prior state of the device may be any earlier state of the device in which the device is guaranteed to be trustworthy. For example, the prior state may correspond to the state that the device is in when it is first deployed or last configured by an administrator. In this way, by providing a mechanism to ensure that the device is still operating in the prior state, the walk-up user may trust that the device is operating as expected.

### BRIEF DESCRIPTION OF THE DRAWINGS

Embodiments of the present invention are illustrated by way of example, and not by way of limitation, in the figures of the accompanying drawings and in which like reference numerals refer to similar elements and in which:

FIG. 1 is a block diagram of an embodiment of the invention;

FIG. 2 is a flowchart illustrating the functional steps performed by an embodiment of the invention;

FIG. 3 is a block diagram of an embodiment of the invention;

FIG. 4 is a flowchart illustrating the functional steps performed by an embodiment of the invention that employs a portable device; and

FIG. 5 is a block diagram that illustrates a computer system upon which an embodiment of the invention may be implemented.

### DETAILED DESCRIPTION

In the following description, for the purposes of explanation, numerous specific details are set forth in order to provide a thorough understanding of the embodiments of the invention described herein. It will be apparent, however, that the embodiments of the invention described herein may be practiced without these specific details. In other instances, well-known structures and devices are shown in block diagram form in order to avoid unnecessarily obscuring the embodiments of the invention described herein.

### Overview

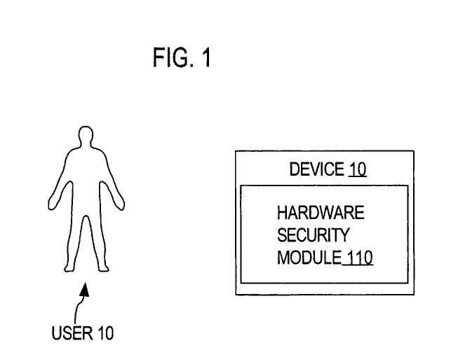

FIG. 1 is a block diagram of an embodiment of the invention. According to the embodiment depicted in FIG. 1, user 10 (hereinafter “walk-up user 10”) may walk up to device 100 for purposes of using device 100. Prior to using device 100, embodiments of the invention allow walk-up user 10 to establish a trust relationship with device 100 by confirming the current state of device 100 is the same as a prior state of device 100. The prior state of the device may be any earlier state of device 100 in which device 100 was guaranteed to be trustworthy. For example, the prior state may correspond to the state that device 100 is in when it is first deployed or last configured by an administrator.

Device 100 may correspond to any machine that is capable of operating in more than one state. For example, illustrative, non-limiting examples of device 100 include a computer, a multi-functional peripheral, a printer, a facsimile machine, a copier, a vending machine, a kiosk, and a phone. As used herein, “state,” refers to any possible state which device 100 may have, including, but not limited to, a security state (i.e., the security configuration) of device 100 and an operational state of device 100.

In an embodiment, when device 100 is known to walk-up user 10 to be in a trusted state, walk-up user may submit to device 100 user input, and in response, receive a response from device 100. Thereafter, anytime that walk-up user 10 wishes to confirm that device 100 is still in the same trusted state, walk-up user 10 may submit the same user input to device 100 for purposes of receiving another response from device 100. Each response generated by the device 100 is based, at least in part, upon the current state of device 100 when the response is generated. The user may then compare the more recent response from device 100 with the prior response received from device 100 to determine whether the state of device 100 has changed since the prior state of device 100, i.e., the trusted state of device 100. If the more recent response is not the same as the prior response from device 100, then walk-up user 10 may be informed that device 100 may not be in a trusted state.

Having provided a high level description of an embodiment, additional embodiments of the invention shall be described in further detail below.

### Verifying the State of a Device

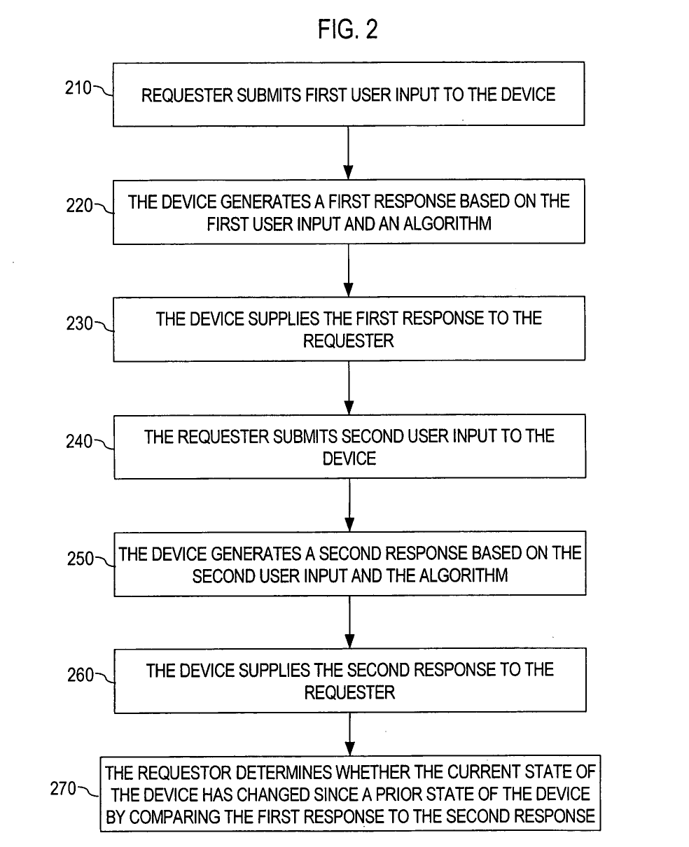

FIG. 2 is a flowchart illustrating the functional steps performed by an embodiment of the invention. In step 210, a requestor submits user input (referred to herein as “first user input”) to device 100. The requester is any person who is physically standing near device 100 and who wishes to confirm whether device 100 may be trusted. For example, the requestor of step 210 may be walk-up user 10 depicted in FIG. 1.

The requestor may submit the first user input to device 100 using a physical interface provided by device 100. For example, device 100 may expose a keypad, touch screen, or graphical user interface that allows the requestor to submit data to device 100.

The first user input of step 210 may be submitted to device 100 when device 100 is known to the requestor to be in a trusted state. For example, device 100 may be in a trusted state after device 100 is first deployed or after an administrator configures device 100.

The first user input may correspond to any type of input that a user may submit to device 100. Non-limiting illustrative examples of the first user input of step 210 include a word, short phrase, an alphanumeric string, any combination letters and/or numbers, biometric data, a voiceprint, and a barcode.

In an embodiment, the first user input of step 210 may be referred to as a challenge code. The challenge code may correspond to a set of input that is a product of the imagination of the requester. In an embodiment, the requestor may select a particular challenge code because the challenge code is easy for the requester to remember. After the performance of step 210, processing proceeds to step 220.

In step 220, device 100 generates a response (referred to herein as “a first response”) based on the received first user input and an algorithm.

In an embodiment, a hardware security module (HSM) 110 may be used by device 100 to aid the performance of step 220. HSM 110, as used herein, corresponds to any combination of hardware and software that may be used to (a) verify that device 100 is operating in the prior state that was known to be trusted, and (b) enable device 100 to access a particular algorithm if device 100 is operating in the prior state that was known to be trusted. HSM 110 may store information that identifies the prior state that was known to be trusted.

If HSM 110 successfully verifies that device 100 is operating in the prior state, then HSM 110 makes available a particular algorithm (the “HSM algorithm”) to device 100. Device 100 may then generate the first response based on the first user input and the HSM algorithm. On the other hand, if HSM 110 does not successfully verify that device 100 is operating in the prior state, then device 100 cannot generate the first response based on the first user input and the HSM algorithm, and instead, generates the first response using some other mechanism, e.g., the first response may be equal to the first user input or be generated, based on the first user input, using another algorithm that is different than the HSM algorithm.

Many different manufacturers make hardware security modules. One example of a particular hardware security module is a Trusted Platform Module (TPM). The most recent specification for the TPM is entitled CG Specification Architecture Overview, version 1.2. This specification is publicly available at the Trusted Computing Group (TCG) website, which, at the time of filing of this application, corresponds to the concatenation of “www,” “.trustedcomputinggroup” and “.org.”

The TPM is a hardware component with embedded logic that may be incorporated into device 100. In an embodiment wherein HSM 110 is a TPM, when device 100 is turned on, the TPM causes device to perform a secure boot cycle. During a secure boot cycle, the TPM causes device 100 to run a series of tests based on the logic embedded in the TPM. The series of tests may verify that any aspect of device 100 currently conforms to an expected state that is stored in the embedded logic of the TPM. For example, the series of tests may verify that the security state or the operational state of device 100 conforms to an expected state that is stored in the embedded logic of the TPM.

In an embodiment, if all of the series of tests performed by the TPM during the secure boot cycle pass, then the TPM allows device 100 to access an algorithm stored by the TPM. In an embodiment, the algorithm may correspond to a private key which device 100 may use to encrypt data. As an example, if all of the series of tests performed by the TPM during the secure boot cycle pass, then device 100 may have access to the private key; alternately, if any of the series of tests performed by the TPM during the secure boot cycle fail, then device 100 would not have access to the private key.

In an embodiment, if HSM 110 is a TPM, and if all of the series of tests performed by the TPM during the secure boot cycle pass, then device 100 may generate the first response by encrypting the first user data received in step 210 using the private key made available by the TPM. Alternately, if HSM 110 is a TPM, and if one of the series of tests performed by the TPM during the secure boot cycle fails, then device 100 may generate the first response any way in which does not involve the private key made available by the TPM, e.g., a different encryption mechanism may be used or the first response may correspond to an unencrypted version of the first user input.

After device 100 generates the first response, processing proceeds to step 230.

In step 230, device 100 supplies the first response to the requester. In an embodiment, device 100 supplies the first response to the requestor through the same interface through which the requestor submitted the first user input to device 100. For example, if the requestor submitted the first user input to device 100 through a graphical user interface provided by device 100, then in step 230 device 100 displays the first response to the requester using the graphical user interface.

After the requestor receives the first response in step 230, at some later point in time the requestor may wish to use device 100. Indeed, enough time may have passed since the performance of step 230 that the requestor may not be certain that device 100 has remained in a trusted state. Consequently, the requestor may wish to confirm that device 100 is still operating in the prior trusted state. As a result, the user may perform step 240 to purposes of confirming that device 100 is still operating in the prior trusted state.

In step 240, the requestor submits another set of user input (referred to herein as “second user input”) to device 100. The requester may submit the second user input to device 100 in any manner described above with respect to the requestor submitting the first user input to device 100.

The value of the second user input should be the same as the first user input. In other words, whatever input the requestor submitted to device 100 as first user input in step 210, the requestor should submit to device 100 as second user input in step 240. Since the requestor thought up the first user input, the requester should remember the first user input. As a result, the requestor should be able to easily remember the first user input, and submit the same input as second user input to device 100 in step 240. After the performance of step 240, processing proceeds to step 250.

In step 250, device 100 generates another response (referred to herein as “a second response”) based on the second user input and the algorithm. In an embodiment, device 100 generates the second response in the same manner in which device 100 generated the first response in step 220. Since the value of the first user input and the second user input is the same, the second response will be the same as the first response if the current state of device 100 has not changed since the prior state of device 100. However, if the current state of device 100 has not changed since the prior state of device 100, even if the value of the first user input and the second user input is the same, the second response will not be the same as the first response. After the second response has been generated by device 100, processing proceeds to step 260.

In step 260, device 100 supplies the second response to the requester. In an embodiment, device 100 supplies the second response to the requestor in step 260 in the same manner as device 100 supplied the first response to the requestor in step 230. After the performance of step 260, processing proceeds to step 270.

In step 270, the requestor determines whether the current state of device 100 has changed since a prior state of device 100. The requestor may perform step 270 by comparing the second response that was just received by the requestor to the first response that was received from device 100 when device 100 was known to be in a trusted state. If the second response is equal to the first response, then the requestor is informed that the current state of device 100 has not changed since a prior state of device 100 when device 100 was known to be in a trusted state. However, if the second response is not equal to the first response, then the requestor is informed that the current state of device 100 has changed since a prior state of device 100 when device 100 was known to be in a trusted state.

When the requestor is informed that the current state of device 100 has not changed since a prior state of device 100 when device 100 was known to be in a trusted state, the requestor may use device 100 confidently with the knowledge that device 100 may be trusted. However, when the requestor is informed that the current state of device 100 has changed since a prior state of device 100 when device 100 was known to be in a trusted state, then the requestor may, among other actions, (a) knowingly assume the risk and use device 100 even though the requestor knows that the current state of device 100 has changed since a prior state of device 100 when device 100 was known to be in a trusted state, (b) use another device, and/or (c) inform an administrator that device 100 that the current state of device 100 has changed since a prior state of device 100 when device 100 was known to be in a trusted state. The interface provided by device 100 may enable the requestor to report to the administrator that the current state of device 100 has changed since a prior state of device 100 when device 100 was known to be in a trusted state. For example, if the requestor configures a control of the interface, the requestor may cause device 100 to send an electronic communication (such as an email, page, facsimile, or recorded phone message) to the administrator to inform the administrator that the current state of device 100 has changed since a prior state of device 100 when device 100 was known to be in a trusted state.

### Using a Portable Device to Verify the State of a Device

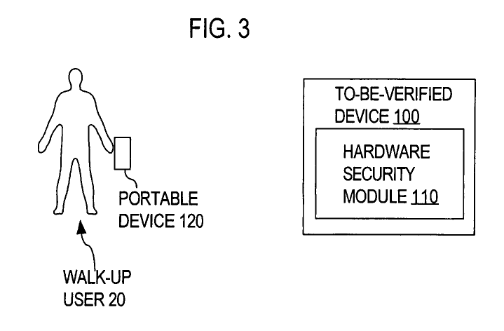

In an embodiment, a walk-up user may carry a portable device that aids in determining whether device 100 may be trusted. FIG. 3 is a block diagram of such an embodiment of the invention. Walk-up user 20 of FIG. 3 carries portable device 120. Portable device 120 corresponds to any machine which (a) is capable of communicating with device 100 (denoted “to-be-verified device 100” hereafter and in FIG. 3 to distinguish over portable device 20), and (b) capable of being carried by walk-up user 20. For example, portable device 20 may correspond to a cell phone, a personal digital assistance (PDA), or a device containing flash memory and a mechanism for exchanging data with device 100, such as a blue tooth component or a USB port interface.

To-be-verified device 100 in FIG. 3 may correspond to any machine that is capable of operating in more than one state. For example, illustrative, non-limiting examples of to-be-verified device 100 include a computer, a multi-functional peripheral, a printer, a facsimile machine, a copier, a vending machine, a kiosk, and a phone.

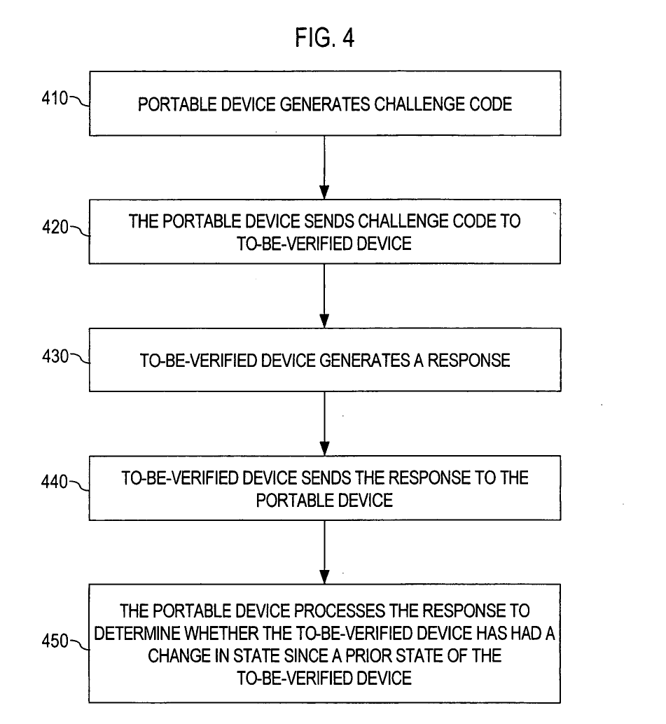

FIG. 4 is a flowchart illustrating the functional steps performed by an embodiment of the invention that employs portable device 120. In step 410, portable device 120 generates a challenge code. A challenge code may correspond to any type of input that a user may submit to device 100. Non-limiting illustrative examples of the challenge code input of step 410 include a word, short phrase, an alphanumeric string, any combination letters and/or numbers, biometric data, a voiceprint, and a barcode. In an embodiment, portable device 120 may generate the challenge code without any help, input, or intervention from the walk-up user. After portable device 120 generates the challenge code, processing proceeds to step 420.

In step 420, portable device 120 sends the challenge code to-be-verified device 100. Portable device 120 may send the challenge code to-be-verified device 100 using any means for transmitting data. In an embodiment, portable device 120 may send the challenge code to-be-verified device 100 over a wireless network. In another embodiment, walk-up user 20 may physically connect portable device 120 with to-be-verified device 100 using a USB port, and thereafter, portable device 120 may send the challenge code to-be-verified device 100 through the USB port. After portable device 120 sends the challenge code to-be-verified device 100, processing proceeds to step 430.

In step 430, to-be-verified device 100 generates a response. To-be-verified device 100 may generate a response in step 430 using HSM 110 on to-be-verified device 100.

If HSM 110 successfully verifies that to-be-verified device 100 is operating in the prior state, then HSM 110 makes available a particular algorithm (the “HSM algorithm”) to device 100. Device 100 may then generate the response based on the challenge code and the HSM algorithm. On the other hand, if HSM 110 does not successfully verify that device 100 is operating in the prior state, then device 100 cannot generate the first response based on the first user input and the HSM algorithm, and instead, generates the response using some other mechanism, e.g., the first response may be equal to the first user input or be generated, based on the first user input, using another algorithm that is different than the HSM algorithm.

In an embodiment, the response may be an encrypted version of the challenge code. For example, the HSM algorithm may correspond to a private key. To illustrate, in an embodiment, if HSM 110 is a TPM, and if all of the series of tests performed by the TPM during the secure boot cycle pass, then to-be-verified device 100 may generate the response by encrypting the first user data received in step 420 using the private key made available by the TPM. Alternately, if HSM 110 is a TPM, and if one of the series of tests performed by the TPM during the secure boot cycle fails, then to-be-verified device 100 may generate the response any way in which does not involve the private key made available by the TPM, e.g., a different encryption mechanism may be used or the first response may correspond to an unencrypted version of the first user input. After to-be-verified device 100 generates the response, processing proceeds to step 440.

In step 440, to-be-verified device 100 sends the response generated in the prior step to portable device 120. To-be-verified device 100 may send the response to portable device 120 in the same manner in which portable device 120 communicated the challenge code to-be-verified device 100 in step 420. After to-be-verified device 100 sends the response to portable device 120, processing proceeds to step 450.

In step 450, portable device 120 processes the response to determine whether to-be-verified device 100 has had a change in state since a prior state of to-be-verified device 100 that was known to be a trusted state. In an embodiment, portable device 120 may determine if to-be-verified device 100 has had a change in state by determining whether the response, received in step 440, has been generated based upon the challenge code and the HSM algorithm provided by HSM 110. If the response was generated based upon the challenge code and the HSM algorithm, then to-be-verified device 100 has not had a change in state since a prior state of to-be-verified device 100 that was known to be a trusted state. On the other hand, if the response was not generated based upon the challenge code and the HSM algorithm, then to-be-verified device 100 has had a change in state since a prior state of to-be-verified device 100 that was known to be a trusted state.

In an embodiment, portable device 120 may process the response in step 450 by decrypting the response to determine whether the response is an encrypted version of the challenge code. In an embodiment, portable device 120 may decrypt the response using a public key associated with to-be-verified device 100. In an embodiment, an administrator of to-be-verified device 100 may store the public key associated with to-be-verified device 100 on portable device 120. Alternately, walk-up user 20 may obtain the public key associated with to-be-verified device 100 by contacting a network location, e.g., the to-be-verified device 100 may provide the requestor with information about where how to obtain the public key of to-be-verified device 100. Thus, in an embodiment, in step 450, portable device 120 may attempt to decrypt the response using the public key associated with to-be-verified device 100 to determine if the decrypted response is equal to the challenge code. If the decrypted response is equal to the challenge code, then portable device 120 may conclude that the response was generated based on the HSM algorithm (in this case the private key associated with to-be-verified device 100), and therefore, to-be-verified device 100 has not had a change in state since a prior state of to-be-verified device 100 that was known to be a trusted state. On the other hand, if the decrypted response is not equal to the challenge code, then portable device 120 may conclude that the response was not generated based on the HSM algorithm (in this case the private key associated with to-be-verified device 100), and therefore, to-be-verified device 100 has had a change in state since a prior state of to-be-verified device 100 that was known to be a trusted state.

In an embodiment, portable device 120 may notify the walk-up user 20 about the determination of whether to-be-verified device 100 has had a change in state since a prior state of to-be-verified device 100 that was known to be trusted. For example, portable device 120 may display a light of a certain color that indicates to-be-verified device 100 has had a change in state since a prior state of to-be-verified device 100 that was known to be trusted, and portable device 120 may display a light of a different color that indicates to-be-verified device 100 has not had a change in state since a prior state of to-be-verified device 100 that was known to be trusted. As another example, portable device 120 may notify the user in other ways, such as through a graphical user interface or by playing an audible sound.

In an embodiment, portable device 120 may inform walk-up user whether or not there was a change in state since a prior state of to-be-verified device 100 that was known to be trusted. In another embodiment, if there was a change in state, portable device 120 may inform walk-up user exactly what was changed since a prior state of to-be-verified device 100 that was known to be trusted, e.g., portable device 120 may display information about what the differences are between the current state of to-be-verified device 100 and the prior state of to-be-verified device. In such an embodiment, to-be-verified device 100 would provide portable device 120 with the information about what the differences are between the current state of to-be-verified device 100 and the prior state of to-be-verified device.

When walk-up user 20 is informed that the current state of to-be-verified device 100 has not changed since the prior state of to-be-verified device 100 when to-be-verified device 100 was known to be in a trusted state, the walk-up user 20 may use device 100 confidently with the knowledge that to-be-verified device 100 may be trusted. However, when the walk-up user 20 is informed that the current state of to-be-verified device 100 has changed since the prior state of to-be-verified device 100 when to-be-verified device 100 was known to be in a trusted state, then the walk-up user 20 may, among other actions, (a) knowingly assume the risk and use to-be-verified device 100 even though the walk-up user 20 knows that the current state of to-be-verified device 100 has changed since a prior state of to-be-verified device 100 when to-be-verified device 100 was known to be in a trusted state, (b) use another device, and/or (c) inform an administrator that to-be-verified device 100 that the current state of to-be-verified device 100 has changed since a prior state of to-be-verified device 100 when to-be-verified device 100 was known to be in a trusted state. The interface provided by to-be-verified device 100 may enable the walk-up user 20 to report to the administrator that the current state of device 100 has changed since a prior state of to-be-verified device 100 when to-be-verified device 100 was known to be in a trusted state. For example, if the walk-up user 20 configures a control of the interface, the walk-up user 20 may cause to-be-verified device 100 to send an electronic communication (such as an email, page, facsimile, or recorded phone message) to the administrator to inform the administrator that the current state of to-be-verified device 100 has changed since a prior state of to-be-verified device 100 when to-be-verified device 100 was known to be in a trusted state.

### Illustrative Uses of Embodiments of the Invention

In an embodiment, the security state of a multi-function peripheral may be confirmed to a user to be in the same state as a prior state that was known to the user to be in a trusted state. In this way, if there were any changes made to the security configurations of the multi-functional peripheral since a prior state that was known to be trusted by the user, then that change in the security state may be detected by the user. For example, if a change is made to an authentication process executing on the multi-function peripheral, or if a change is made to a firewall executing on the multi-functional peripheral, then this change may be detected by the user.

In another embodiment, the operational state of a printer may be confirmed to a user to be in the same state as a prior state that was known to the user to be in a trusted state. In this way, if there were any changes made to the operational state of the printer since a prior state that was known to be trusted by the user, then the user may detect that change in the operational state. For example, if the printer runs out of ink or paper or a feature supported by the printer is not working properly, then this change in operational state may be detected by the user.

In another embodiment, the operational state of a vending machine may be confirmed to a user to be in the same state as a prior state that was known to the user to be in a trusted state. In this way, if there were any changes made to the operational state of the vending machine since a prior state that was known to be trusted, then that change in the operational state may be detected by the user. For example, if the vending machine runs out of an item that is sold by the vending machine or if the vending machine is not operating properly, then this change in operational state may be detected by the user. In the embodiment depicted in FIG. 4, if portable device 120 does not currently have the algorithm (such as a public key associated with the vending machine) employed by HSM 110 of the vending machine, then portable device 120 may be able to obtain the algorithm by contacting a wireless network to obtain the algorithm.

The illustrative embodiments described in this section are not meant to fully enumerate all embodiments of the invention, as the inventors complete that device 100 may cover a wide range of machines. Further, it is contemplated that any state of device 100 may be confirmed using embodiments of the invention, as the state need not be limited to a security state or an operational state of device 100.

### Implementing Mechanisms

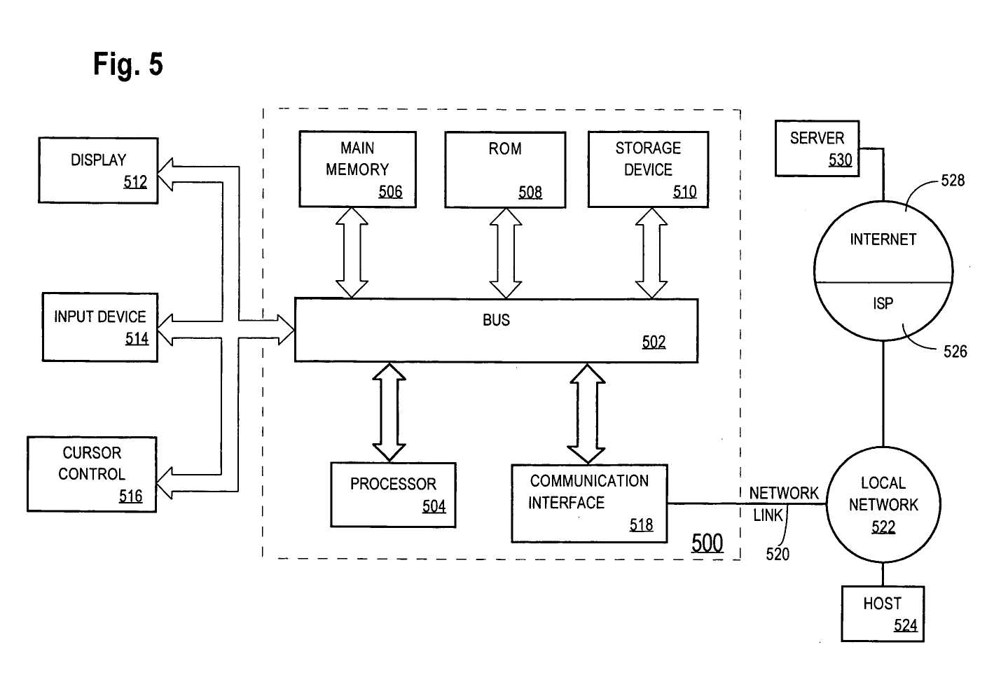

In an embodiment, one or more of portable device 120 and device 100 may be implemented on or using a computer system. FIG. 5 is a block diagram that illustrates a computer system 500 upon which an embodiment of the invention may be implemented. Computer system 500 includes a bus 502 or other communication mechanism for communicating information, and a processor 504 coupled with bus 502 for processing information. Computer system 500 also includes a main memory 506, such as a random access memory (RAM) or other dynamic storage device, coupled to bus 502 for storing information and instructions to be executed by processor 504. Main memory 506 also may be used for storing temporary variables or other intermediate information during execution of instructions to be executed by processor 504. Computer system 500 further includes a read only memory (ROM) 508 or other static storage device coupled to bus 502 for storing static information and instructions for processor 504. A storage device 510, such as a magnetic disk or optical disk, is provided and coupled to bus 502 for storing information and instructions.

Computer system 500 may be coupled via bus 502 to a display 512, such as a cathode ray tube (CRT), for displaying information to a computer user. An input device 514, including alphanumeric and other keys, is coupled to bus 502 for communicating information and command selections to processor 504. Another type of user input device is cursor control 516, such as a mouse, a trackball, or cursor direction keys for communicating direction information and command selections to processor 504 and for controlling cursor movement on display 512. This input device typically has two degrees of freedom in two axes, a first axis (e.g., x) and a second axis (e.g., y), that allows the device to specify positions in a plane.

The invention is related to the use of computer system 500 for implementing the techniques described herein. According to one embodiment of the invention, those techniques are performed by computer system 500 in response to processor 504 executing one or more sequences of one or more instructions contained in main memory 506. Such instructions may be read into main memory 506 from another machine-readable medium, such as storage device 510. Execution of the sequences of instructions contained in main memory 506 causes processor 504 to perform the process steps described herein. In alternative embodiments, hard-wired circuitry may be used in place of or in combination with software instructions to implement the invention. Thus, embodiments of the invention are not limited to any specific combination of hardware circuitry and software.

The term “machine-readable medium” as used herein refers to any medium that participates in providing data that causes a machine to operation in a specific fashion. In an embodiment implemented using computer system 500, various machine-readable media are involved, for example, in providing instructions to processor 504 for execution. Such a medium may take many forms, including but not limited to, non-volatile media, volatile media, and transmission media. Non-volatile media includes, for example, optical or magnetic disks, such as storage device 510. Volatile media includes dynamic memory, such as main memory 506. Transmission media includes coaxial cables, copper wire and fiber optics, including the wires that comprise bus 502. Transmission media can also take the form of acoustic or light waves, such as those generated during radio-wave and infra-red data communications. All such media must be tangible to enable the instructions carried by the media to be detected by a physical mechanism that reads the instructions into a machine.

Common forms of machine-readable media include, for example, a floppy disk, a flexible disk, hard disk, magnetic tape, or any other magnetic medium, a CD-ROM, any other optical medium, punchcards, papertape, any other physical medium with patterns of holes, a RAM, a PROM, and EPROM, a FLASH-EPROM, any other memory chip or cartridge, a carrier wave as described hereinafter, or any other medium from which a computer can read.

Various forms of machine-readable media may be involved in carrying one or more sequences of one or more instructions to processor 504 for execution. For example, the instructions may initially be carried on a magnetic disk of a remote computer. The remote computer can load the instructions into its dynamic memory and send the instructions over a telephone line using a modem. A modem local to computer system 500 can receive the data on the telephone line and use an infra-red transmitter to convert the data to an infra-red signal. An infra-red detector can receive the data carried in the infra-red signal and appropriate circuitry can place the data on bus 502. Bus 502 carries the data to main memory 506, from which processor 504 retrieves and executes the instructions. The instructions received by main memory 506 may optionally be stored on storage device 510 either before or after execution by processor 504.

Computer system 500 also includes a communication interface 518 coupled to bus 502. Communication interface 518 provides a two-way data communication coupling to a network link 520 that is connected to a local network 522. For example, communication interface 518 may be an integrated services digital network (ISDN) card or a modem to provide a data communication connection to a corresponding type of telephone line. As another example, communication interface 518 may be a local area network (LAN) card to provide a data communication connection to a compatible LAN. Wireless links may also be implemented. In any such implementation, communication interface 518 sends and receives electrical, electromagnetic or optical signals that carry digital data streams representing various types of information.

Network link 520 typically provides data communication through one or more networks to other data devices. For example, network link 520 may provide a connection through local network 522 to a host computer 524 or to data equipment operated by an Internet Service Provider (ISP) 526. ISP 526 in turn provides data communication services through the world wide packet data communication network now commonly referred to as the “Internet” 528. Local network 522 and Internet 528 both use electrical, electromagnetic or optical signals that carry digital data streams. The signals through the various networks and the signals on network link 520 and through communication interface 518, which carry the digital data to and from computer system 500, are exemplary forms of carrier waves transporting the information.

Computer system 500 can send messages and receive data, including program code, through the network(s), network link 520 and communication interface 518. In the Internet example, a server 530 might transmit a requested code for an application program through Internet 528, ISP 526, local network 522 and communication interface 518.

The received code may be executed by processor 504 as it is received, and/or stored in storage device 510, or other non-volatile storage for later execution. In this manner, computer system 500 may obtain application code in the form of a carrier wave.

In the foregoing specification, embodiments of the invention have been described with reference to numerous specific details that may vary from implementation to implementation. Thus, the sole and exclusive indicator of what is the invention, and is intended by the applicants to be the invention, is the set of claims that issue from this application, in the specific form in which such claims issue, including any subsequent correction. Any definitions expressly set forth herein for terms contained in such claims shall govern the meaning of such terms as used in the claims. Hence, no limitation, element, property, feature, advantage or attribute that is not expressly recited in a claim should limit the scope of such claim in any way. The specification and drawings are, accordingly, to be regarded in an illustrative rather than a restrictive sense.

What is claimed is:

1. A method, comprising:
in response to a device receiving first user input from a requester, the device generating a first response, based on the first user input, using an algorithm;
supplying the first response to the requestor;
in response to the device receiving, subsequent to the receipt of the first user input, second user input from the requestor, the device verifying whether a current state of the device has changed since a prior state of the device, wherein the first user input and the second user input are equal;
upon the device determining that the current state of the device has not changed since the prior state of the device, generating a second response using the algorithm, wherein the first response is the same as the second response if the current state of the device has not changed since the prior state of the device; and
supplying the second response to the requestor.

2. The method of claim 1, wherein the second user input is submitted to the device by the requestor using a physical interface provided by the device.

3. The method of claim 1, wherein the current state of the device corresponds to a security state of the device.

4. The method of claim 1, wherein the current state of the device corresponds to an operational state of the device.

5. The method of claim 1, wherein the device corresponds to one of: a computer, a multi-functional peripheral, a printer, a facsimile machine, a copier, a vending machine, a kiosk, and a phone.

6. A method, comprising:
in response to a first device receiving user input from a portable device, the first device verifying whether a current state of the first device has changed since a prior state of the first device;
upon the first device determining that the current state of the first device has not changed since the prior state of the first device, generating a response using an algorithm; and
supplying the response to the portable device, wherein the portable device is configured to determine whether the current state of the device has changed since the prior state of the device based upon the response.

7. The method of claim 6, wherein the response is an encrypted version of the user input.

8. The method of claim 6, wherein the portable device is configured to display a visual indication of whether the current state of the first device has changed since the prior state.

9. The method of claim 6, wherein the current state of the first device corresponds to a security state of the device.

10. The method of claim 6, wherein the current state of the first device corresponds to an operational state of the device.

11. The method of claim 6, wherein the first device corresponds to one of: a multi-functional peripheral, a printer, a facsimile machine, a copier, a vending machine, a kiosk, and a phone.

12. A machine-readable medium, carrying one or more sequences of instructions, which when executed by one or more processors, cause:
in response to a device receiving first user input from a requestor, the device generating a first response, based on the first user input, using an algorithm;
supplying the first response to the requester;
in response to the device receiving, subsequent to the receipt of the first user input, second user input from the requester, the device verifying whether a current state of the device has changed since a prior state of the device, wherein the first user input and the second user input are equal;
upon the device determining that the current state of the device has not changed since the prior state of the device, generating a second response using the algorithm, wherein the first response is the same as the second response if the current state of the device has not changed since the prior state of the device; and
supplying the second response to the requestor.

13. The machine-readable medium of claim 12, wherein the second user input is submitted to the device by the requestor using a physical interface provided by the device.

14. The machine-readable medium of claim 12, wherein the current state of the device corresponds to a security state of the device.

15. The machine-readable medium of claim 12, wherein the current state of the device corresponds to an operational state of the device.

16. The machine-readable medium of claim 12, wherein the device corresponds to one of: a computer, a multi-functional peripheral, a printer, a facsimile machine, a copier, a vending machine, a kiosk, and a phone.

17. A machine-readable medium, carrying one or more sequences of instructions, which when executed by one or more processors, cause:
in response to a first device receiving user input from a portable device, the first device verifying whether a current state of the first device has changed since a prior state of the first device;
upon the first device determining that the current state of the first device has not changed since the prior state of the first device, generating a response using an algorithm; and
supplying the response to the portable device, wherein the portable device is configured to determine whether the current state of the device has changed since the prior state of the device based upon the response.

18. The machine-readable medium of claim 17, wherein the response is an encrypted version of the user input.

19. The machine-readable medium of claim 17, wherein the portable device is configured to display a visual indication of whether the current state of the first device has changed since the prior state.

20. The machine-readable medium of claim 17, wherein the current state of the first device corresponds to a security state of the device.

21. The machine-readable medium of claim 17, wherein the current state of the first device corresponds to an operational state of the device.

22. The machine-readable medium of claim 17, wherein the first device corresponds to one of: a multi-functional peripheral, a printer, a facsimile machine, a copier, a vending machine, a kiosk, and a phone.

23. An apparatus, comprising:
one or more processors; and
a machine-readable medium carrying one or more sequences of instructions, which when executed by the one or more processors, causes:
in response to a device receiving first user input from a requestor, the device generating a first response, based on the first user input, using an algorithm;
supplying the first response to the requestor;
in response to the device receiving, subsequent to the receipt of the first user input, second user input from the requester, the device verifying whether a current state of the device has changed since a prior state of the device, wherein the first user input and the second user input are equal;
upon the device determining that the current state of the device has not changed since the prior state of the device, generating a second response using the algorithm, wherein the first response is the same as the second response if the current state of the device has not changed since the prior state of the device; and
supplying the second response to the requestor.

24. The apparatus of claim 23, wherein the second user input is submitted to the device by the requestor using a physical interface provided by the device.

25. The apparatus of claim 23, wherein the current state of the device corresponds to a security state of the device.

26. The apparatus of claim 23, wherein the current state of the device corresponds to an operational state of the device.

27. The apparatus of claim 23, wherein the device corresponds to one of: a computer, a multi-functional peripheral, a printer, a facsimile machine, a copier, a vending machine, a kiosk, and a phone.

28. An apparatus, comprising:
one or more processors; and
a machine-readable medium carrying one or more sequences of instructions, which when executed by the one or more processors, causes:
in response to a first device receiving user input from a portable device, the first device verifying whether a current state of the first device has changed since a prior state of the first device;
upon the first device determining that the current state of the first device has not changed since the prior state of the first device, generating a response using an algorithm; and
supplying the response to the portable device, wherein the portable device is configured to determine whether the current state of the device has changed since the prior state of the device based upon the response.

29. The apparatus of claim 28, wherein the response is an encrypted version of the user input.

30. The apparatus of claim 28, wherein the portable device is configured to display a visual indication of whether the current state of the first device has changed since the prior state.

31. The apparatus of claim 28, wherein the current state of the first device corresponds to a security state of the device.

32. The apparatus of claim 28, wherein the current state of the first device corresponds to an operational state of the device.

33. The apparatus of claim 28, wherein the first device corresponds to one of: a multi-functional peripheral, a printer, a facsimile machine, a copier, a vending machine, a kiosk, and a phone.
